(19) United States
(12) Patent Application Publication
(10) Pub. No.: US 2007/0165359 A1
(43) Pub. Date: Jul. 19, 2007

(54) Thin-film device and method of manufacturing same

(75) Inventors: Hajime Kuwajima, Tokyo (JP); Masahiro Miyazaki, Tokyo (JP); Akira Furuya, Tokyo (JP)

Correspondence Address: OLIFF & BERRIDGE, PLC, P.O. BOX 19928, ALEXANDRIA, VA, 22320, US

(73) Assignee: TDK CORPORATION, TOKYO (JP)

(21) Appl. No.: 11/604,215

(22) Filed: Nov. 27, 2006

(30) Foreign Application Priority Data
Dec. 27, 2005 (JP) 2005-373937

(51) Int. Cl. H01G 4/005; H01L 29/00

(52) U.S. Cl. 361/303; 257/532

(57) ABSTRACT

A thin-film device comprises: a substrate; a flattening film made of an insulating material and disposed on the substrate; and a capacitor provided on the flattening film. The capacitor incorporates: a lower conductor layer; a dielectric film disposed on the lower conductor layer; and an upper conductor layer disposed on the dielectric film. The lower conductor layer incorporates: an electrode film; a first layer formed on the electrode film by electroplating; and a second layer formed on the first layer by PVD or CVD. The grain diameter of a metallic crystal of the second layer is smaller than that of the first layer.

### BACKGROUND OF THE INVENTION

1. Field of the Invention

The present invention relates to a thin-film device comprising a lower conductor layer, a dielectric film and an upper conductor layer that are stacked, and to a method of manufacturing such a thin-film device.

2. Description of the Related Art

With increasing demands for reductions in dimensions and thickness of high frequency electronic apparatuses such as cellular phones, reductions in dimensions and profile of electronic components mounted on the high frequency electronic apparatuses have been sought. Some of the electronic components comprise capacitors. Each capacitor typically incorporates a dielectric layer and a pair of conductor layers disposed to sandwich the dielectric layer.

To achieve reductions in dimensions and profile of an electronic component comprising a capacitor, important factors are a reduction in area of a region in which the pair of conductor layers are opposed to each other with the dielectric layer disposed in between and a reduction in the number of layers making up the capacitor. Basically, in prior art, a material having a high permittivity is used as a dielectric material forming the dielectric layer and the thickness of the dielectric layer is reduced to achieve a reduction in area of the above-mentioned region and a reduction in the number of the layers making up the capacitor.

As conventional electronic components comprising capacitors, a thin-film capacitor disclosed in Japanese Published Patent Application (hereinafter referred to as JP-A) 2003-347155 and a thin-film capacitor element disclosed in JP-A 2003-17366 are known. The thin-film capacitor disclosed in JP-A 2003-347155 incorporates a lower electrode layer, a dielectric layer and an upper electrode layer formed one by one on a substrate through the use of thin-film forming techniques. The thin-film capacitor element disclosed in JP-A 2003-17366 incorporates a lower electrode, a dielectric layer and an upper electrode formed one by one on a substrate through the use of thin-film forming techniques. JP-A 2003-17366 discloses a technique in which the top surface of the lower electrode and that of an insulator layer disposed around the lower electrode are flattened and the dielectric layer is formed on the flattened top surfaces. An electronic component formed through thin-film forming techniques such as the above-mentioned thin-film capacitor and thin-film capacitor element is called a thin-film device in the present patent application.

JP-A 2002-93952 discloses a substrate for electronic components, the substrate comprising: an insulating substrate; a base electrode formed on the insulating substrate by a thin-film forming method; an Ni plating film having a thickness of 0.5 to 1.0 μm and formed on the base electrode; and a second plating film formed on the Ni plating film and made of a metal having a better solderability than Ni.

For a thin-film device comprising a capacitor, since the dielectric layer is formed through thin-film forming techniques, it is possible to reduce the thickness of the dielectric layer and to thereby reduce the profile of the thin-film device. However, if the thickness of the dielectric layer is reduced in the thin-film device comprising a capacitor, there arise problems that the characteristics of the capacitor become different from those intended, the withstand voltage of the capacitor is reduced, and variations in withstand voltage of the capacitor among products are increased. These problems will now be described in detail with reference to FIG. 12.

FIG. 12 is a cross-sectional view illustrating an example of configuration of a thin-film device comprising a capacitor. The thin-film device of FIG. 12 comprises: a lower conductor layer 102 disposed on a substrate 101; a dielectric layer 103 disposed on the substrate 101 and the lower conductor layer 102; and an upper conductor layer 104 disposed in a region sandwiching the dielectric layer 103 with the lower conductor layer 102. The thin-film device is fabricated by forming the lower conductor layer 102, the dielectric layer 103 and the upper conductor layer 104 in this order on the substrate 101 through the use of thin-film forming techniques.

In the thin-film device of FIG. 12, it is required that the lower conductor layer 102 have a certain thickness so that it is possible to feed a sufficient current thereto. Therefore, for example, electroplating is used to form the lower conductor layer 102. In electroplating, metallic ions having reached the surface of an object to be plated receive electrons and are thereby reduced to metal and taken into a metallic crystal lattice, so that the metallic crystal grows. If this process of metallic crystal growth reaches completion, the plating film reaches an equilibrium state. However, immediately after the plating film is formed, there may exist portions that have not reached the equilibrium state wherein the above-mentioned process of metallic crystal growth has not completed. Considering a case of forming a copper plating film by way of example, there may exist unreacted residual substances such as cupric sulfate, phosphorus, chlorine and sodium in the above-mentioned portions of the plating film that have not reached the equilibrium state. If the dielectric layer 103 is formed on the lower conductor layer 102 containing such residual substances, the residual substances in the lower conductor layer 102 may diffuse into the dielectric layer 103. As a result, there is a possibility that the characteristics of the dielectric layer 103 such as permittivity and dielectric loss tangent may change to become different from those intended. Possible consequences are that: the characteristics of the capacitor may become different from those intended; withstand voltage of the capacitor may be reduced due to a reduction in insulation of the dielectric layer 103; and variations in characteristics and withstand voltage of the capacitor among products may increase.

If the dielectric layer 103 is formed on the lower conductor layer 102 including portions that have not reached the equilibrium state, the lower conductor layer 102 is heated in the course of forming the dielectric layer 103, which may cause a change in the state of the portions of the lower conductor layer 102 that have not reached the equilibrium state. As a result, the surface roughness of the top surface of the lower conductor layer 102 touching the dielectric layer 103 may be increased. If the surface roughness of the top surface of the lower conductor layer 102 is thus increased, the thickness of the dielectric layer 103 is made nonuniform. Consequently, a portion that is extremely small in thickness develops in the dielectric layer 103, and insulation in the portion is degraded, which may result in an extreme reduction in withstand voltage of the capacitor. In such a case, a short-circuit failure of the capacitor resulting from a puncture of the dielectric layer 103, for example, is likely to occur. Furthermore, if the thickness of the dielectric layer 103 is nonuniform, variations in withstand voltage of the capacitor among products are increased.

In a case in which the thin-film device comprising a capacitor is designed for high frequency applications, if the surface roughness of the top surface of the lower conductor layer 102 is great, the skin resistance of the lower conductor layer 102 increases, and the signal transmission characteristic of the lower conductor layer 102 may be thereby degraded.

No measures to solve the foregoing problems are disclosed in any of JP-A 2003-347155, JP-A 2003-17366 and JP-A 2002-93952. The foregoing problems apply not only to thin-film devices comprising capacitors but also to thin-film devices in general each comprising a lower conductor layer, a dielectric film and an upper conductor layer that are stacked.

### OBJECT AND SUMMARY OF THE INVENTION

It is an object of the invention to provide a thin-film device comprising a lower conductor layer, a dielectric film and an upper conductor layer that are stacked, the thin-film device being capable of preventing changes in characteristics of the dielectric film and a reduction in uniformity of the thickness of the dielectric film resulting from portions of the lower conductor layer that have not reached an equilibrium state, and to provide a method of manufacturing such a thin-film device.

A thin-film device of the invention comprises: a lower conductor layer; a dielectric film disposed on the lower conductor layer; and an upper conductor layer disposed on the dielectric film.

In the thin-film device of the invention, the lower conductor layer incorporates: a first layer made of a metal; and a second layer made of a metal and disposed between the first layer and the dielectric film. The grain diameter of a metallic crystal of the second layer is smaller than that of the first layer.

In the thin-film device of the invention, the grain diameter of the metallic crystal of the second layer of the lower conductor layer is smaller than that of the first layer of the lower conductor layer. Such a relationship can be achieved by, for example, forming the first layer by electroplating and forming the second layer by physical vapor deposition or chemical vapor deposition. In this case, the second layer is in a nearly equilibrium state as it is formed.

A method of manufacturing the thin-film device of the invention comprises the steps of: forming the first layer by electroplating; forming the second layer on the first layer by physical vapor deposition or chemical vapor deposition; forming the dielectric film on the second layer; and forming the upper conductor layer on the dielectric film.

According to the method of manufacturing the thin-film device of the invention, the first layer of the lower conductor layer is formed by electroplating, and the second layer of the lower conductor layer is formed by physical vapor deposition or chemical vapor deposition. The second layer formed by such a process is in a nearly equilibrium state as it is formed.

In the method of the invention, the grain diameter of the metallic crystal of the second layer may be smaller than that of the first layer.

In the thin-film device of the invention or the method of manufacturing the same, the surface roughness in maximum height of the top surface of the second layer may be smaller than that of the top surface of the first layer.

In the thin-film device of the invention or the method of manufacturing the same, the dielectric film may have a thickness that falls within a range of 0.02 to 1 μm inclusive.

In the thin-film device of the invention or the method of manufacturing the same, the metal forming the first layer may contain any of Cu, Ag and Al, and the metal forming the second layer may contain any of Cu, Ag, Al, Cr, Ti, Ni, Ni—Cr and Au.

In the thin-film device of the invention or the method of manufacturing the same, the lower conductor layer, the dielectric film and the upper conductor layer may constitute a capacitor.

According to the thin-film device of the invention, the lower conductor layer incorporates: the first layer made of a metal; and the second layer made of a metal and disposed between the first layer and the dielectric film. The grain diameter of the metallic crystal of the second layer is smaller than that of the first layer. Such a relationship can be achieved by, for example, forming the first layer by electroplating and forming the second layer by physical vapor deposition or chemical vapor deposition. As a result, the second layer is in a nearly equilibrium state as it is formed. According to the invention, it is thereby possible to prevent changes in characteristics of the dielectric film and a reduction in uniformity of the thickness of the dielectric film resulting from portions of the lower conductor layer that have not reached an equilibrium state.

According to the method of manufacturing the thin-film device of the invention, the first layer of the lower conductor layer is formed by electroplating, and the second layer is formed by physical vapor deposition or chemical vapor deposition. The second layer formed by such a process is in a nearly equilibrium state as it is formed. According to the invention, it is thereby possible to prevent changes in characteristics of the dielectric film and a reduction in uniformity of the thickness of the dielectric film resulting from portions of the lower conductor layer that have not reached an equilibrium state.

Other and further objects, features and advantages of the invention will appear more fully from the following description.

### BRIEF DESCRIPTION OF THE DRAWINGS

FIG. 1 is a cross-sectional view of a thin-film device of an embodiment of the invention.

FIG. 2 is a cross-sectional view illustrating a step of a method of manufacturing the thin-film device of the embodiment of the invention.

FIG. 3 is a cross-sectional view illustrating a step that follows the step of FIG. 2.

FIG. 4 is a cross-sectional view illustrating a step that follows the step of FIG. 3.

FIG. 5 is a cross-sectional view illustrating a step that follows the step of FIG. 4.

FIG. 6 is a cross-sectional view illustrating a step that follows the step of FIG. 5.

FIG. 7 is a cross-sectional view illustrating a step that follows the step of FIG. 6.

FIG. 8 is a cross-sectional view illustrating a step that follows the step of FIG. 7.

FIG. 9 is a cross-sectional view illustrating a step that follows the step of FIG. 8.

FIG. 10 is a cross-sectional view illustrating a step that follows the step of FIG. 9.

FIG. 11 is a cross-sectional view illustrating a step that follows the step of FIG. 10.

FIG. 12 is a cross-sectional view illustrating an example of configuration of a thin-film device comprising a capacitor.

### DESCRIPTION OF A PREFERRED EMBODIMENT

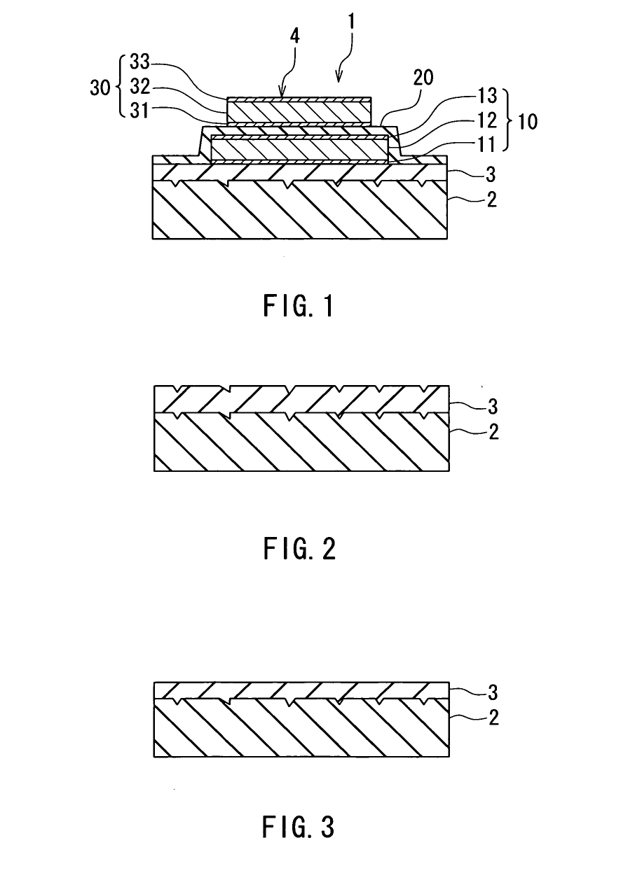

A preferred embodiment of the invention will now be described with reference to the accompanying drawings. Reference is now made to FIG. 1 to describe a thin-film device of an embodiment of the invention. FIG. 1 is a cross-sectional view of the thin-film device of the embodiment. As shown in FIG. 1, the thin-film device 1 of the embodiment comprises: a substrate 2; a flattening film 3 made of an insulating material and disposed on the substrate 2; and a capacitor 4 provided on the flattening film 3. The capacitor 4 incorporates: a lower conductor layer 10 disposed on the flattening film 3; a dielectric film 20 disposed on the lower conductor layer 10; and an upper conductor layer 30 disposed on the dielectric film 20.

Each of the lower conductor layer 10 and the upper conductor layer 30 is patterned into a specific shape. The dielectric film 20 is disposed to cover the top and side surfaces of the lower conductor layer 10 and the top surface of the flattening film 3. The upper conductor layer 30 is disposed in a region sandwiching the dielectric film 20 with the lower conductor layer 10. The lower conductor layer 10 and the upper conductor layer 30 make up a pair of electrodes opposed to each other with the dielectric film 20 disposed in between in the capacitor 4.

The substrate 2 is made of an insulating material (a dielectric material). The insulating material forming the substrate 2 may be an inorganic material or an organic material. The insulating material forming the substrate 2 may be Al₂O₃, for example. The substrate 2 may be made of a semiconductor material.

The insulating material forming the flattening film 3 may be an inorganic material or an organic material. An inorganic material forming the flattening film 3 is Al₂O₃, for example. When an inorganic material is used as the material of the flattening film, it is preferred to form the flattening film 3 by physical vapor deposition (PVD) or chemical vapor deposition (CVD). An organic material forming the flattening film 3 may be a resin, for example. In this case, the resin may be either a thermoplastic resin or a thermosetting resin. When an organic material such as a resin is used as the material of the flattening film 3, it is preferred that the organic material to form the flattening film 3 be applied to the top of the substrate 2 while the material exhibits fluidity, and then the organic material be hardened to form the flattening film 3. The flattening film 3 may be made of a spin-on-glass (SOG) film. The flattening film 3 may be formed through an ink-jet technique.

The surface roughness in maximum height Rz of the top surface of the flattening film 3 is smaller than the surface roughness in maximum height Rz of the top surface of the substrate 2. The surface roughness in maximum height Rz is one of parameters indicating the surface roughness and is defined as a sum of the maximum value of the peak and the maximum value of the valley of a contour curve of a unit length. The thickness of the flattening film 3 preferably falls within a range of 0.01 to 50 μm inclusive.

If the surface roughness of the top surface of the substrate 2 is sufficiently small, the lower conductor layer 10 may be disposed directly on the substrate 2 without providing the flattening film 3.

The lower conductor layer 10 incorporates: an electrode film 11 made of a metal and disposed on the flattening film 3; a first layer 12 made of a metal and disposed on the electrode film 11; and a second layer 13 made of a metal and disposed between the first layer 12 and the dielectric film 20. The grain diameter of the metallic crystal of the second layer 13 is smaller than that of the first layer 12. In addition, it is preferred that the surface roughness in maximum height Rz of the top surface of the second layer 13 be smaller than that of the top surface of the first layer 12.

The metal forming the first layer 12 contains any of Cu, Ag and Al, for example. The metal forming the second layer 13 contains any of Cu, Ag, Al, Cr, Ti, Ni, Ni—Cr and Au, for example.

The first layer 12 is formed by electroplating. The electrode film 11 is used as an electrode for forming the first layer 12 by electroplating. The second layer 13 is formed by PVD or CVD.

The dielectric film 20 is made of a dielectric material. The dielectric material forming the dielectric film 20 is preferably an inorganic material. The dielectric material forming the dielectric film 20 may be any of Al₂O₃, Si₄N₃ and SiO₂, for example.

The upper conductor layer 30 has a configuration the same as that of the lower conductor layer 10, for example. That is, the upper conductor layer 30 incorporates: an electrode film 31 made of a metal and disposed on the dielectric film 20; a first layer 32 made of a metal and disposed on the electrode film 31; and a second layer 33 made of a metal and disposed between the first layer 32 and the dielectric film 20. The grain diameter of the metallic crystal of the second layer 33 is smaller than that of the first layer 32. In addition, it is preferred that the surface roughness in maximum height Rz of the top surface of the second layer 33 be smaller than that of the top surface of the first layer 32. It is not necessarily required that the upper conductor layer 30 have a configuration the same as that of the lower conductor layer 10 if it is not necessary to stack a dielectric layer on the upper conductor layer 30. For example, it is not always necessary that the upper conductor layer 30 incorporate the second layer 33.

The metals forming the first layer 32 and the second layer 33 and the methods of forming the first layer 32 and the second layer 33 are the same as those for the first layer 12 and the second layer 13 of the lower conductor layer 10.

The thickness of the dielectric film 20 is smaller than that of the lower conductor layer 10 and preferably falls within a range of 0.02 to 1 μm inclusive, for example, and more preferably a range of 0.05 to 0.5 μm inclusive. The thickness of the lower conductor layer 10 preferably falls within a range of 5 to 10 μm inclusive. The thickness of the upper conductor layer 30 preferably falls within a range of 5 to 10 μm inclusive.

The reason why it is preferred that the thicknesses of the lower conductor layer 10 and the upper conductor layer 30 fall within the above-mentioned ranges will now be described. The thin-film device of the embodiment is used in a band-pass filter for a wireless local area network (LAN) or for a cellular phone. For the wireless LAN a frequency band of 2.5 GHz is used. Considering the passing loss in this frequency band, it is required that the thickness of each of the lower conductor layer 10 and the upper conductor layer 30 be 3 μm or greater. That is, if the thickness of each of the lower conductor layer 10 and the upper conductor layer 30 is smaller than 3 μm, the passing loss will be too great. In addition, a frequency band of 800 MHz to 1.95 GHz is used for cellular phones. To improve the attenuation characteristic of the band-pass filter and to suppress noise at low frequencies in this frequency band in particular, it is required that the thickness of each of the lower conductor layer 10 and the upper conductor layer 30 be 5 μm or greater. Therefore, it is preferred that the thickness of each of the lower conductor layer 10 and the upper conductor layer 30 be 5 μm or greater. On the other hand, if each of the lower conductor layer 10 and the upper conductor layer 30 is too thick, the surface roughness of the top surface of each of the lower conductor layer 10 and the upper conductor layer 30 is increased and the skin resistance of each of the lower conductor layer 10 and the upper conductor layer 30 is thereby increased, or it becomes necessary to perform flattening processing for reducing the surface roughness of the top surface of each of the lower conductor layer 10 and the upper conductor layer 30, which requires time and labor. Therefore, it is practically preferred that the thickness of each of the lower conductor layer 10 and the upper conductor layer 30 be 10 μm or smaller.

Reference is now made to FIG. 2 to FIG. 11 to describe a method of manufacturing the thin-film device 1 of the embodiment. Although examples of materials and thicknesses of the layers are given in the following description, those examples are non-limiting for the method of the embodiment.

FIG. 2 is a cross-sectional view illustrating a step of the method of manufacturing the thin-film device 1 of the embodiment. In the method, first, as shown in FIG. 2, the flattening film 3 is formed on the substrate 2. Here, by way of example, the insulating material forming the flattening film 3 is Al₂O₃ that is an inorganic material, and the flattening film 3 is formed by PVD or CVD. The flattening film 3 thus formed is more closely packed than a ceramic. The thickness of the flattening film 3 at this point is 5.5 μm, for example.

Next, as shown in FIG. 3, the top surface of the flattening film 3 is flattened by polishing. A method of this polishing is chemical mechanical polishing (CMP), for example. The thickness of the flattening film 3 polished is 2.0 μm, for example. Here, by way of example, the surface roughness in maximum height Rz of the top surface of the flattening film 3 polished is 30 nm. The method of polishing the top surface of the flattening film 3 is not limited to CMP but may be any other polishing method such as buffing, lapping and die polishing. The processing of flattening the top surface of the flattening film 3 may be performed by a combination of two or more polishing methods. It is not necessary to flatten the top surface of the flattening film 3 by polishing in such a case that the surface roughness in maximum height Rz of the top surface of the flattening film 3 is made sufficiently small without flattening the top surface of the flattening film 3.

The flattening film 3 may be made of an organic material such as a resin. In this case, the flattening film 3 may be formed in such a manner that the organic material to form the flattening film 3 is applied to the top of the substrate 2 while the material exhibits fluidity, and then the organic material is hardened. The flattening film 3 may be made of a spin-on-glass (SOG) film. The flattening film 3 may be formed through an ink-jet technique. In these cases, it is possible to make the surface roughness in maximum height Rz of the top surface of the flattening film 3 sufficiently small without polishing the top surface of the flattening film 3.

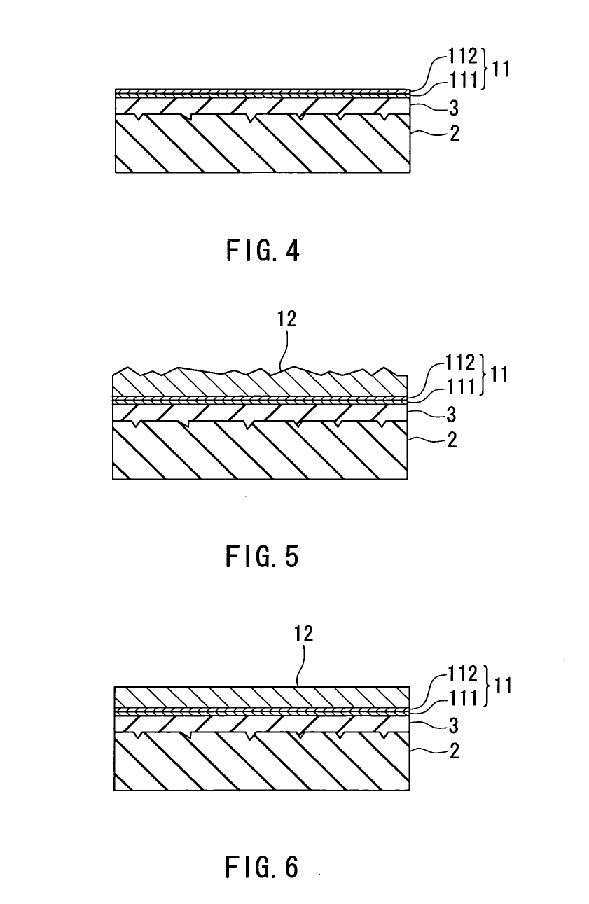

Next, as shown in FIG. 4, the electrode film 11 is formed on the substrate 2 by sputtering, for example. Here is given an example in which the electrode film 11 is made up of two layers including a first electrode film 111 and a second electrode film 112. The first electrode film 111 and the second electrode film 112 are formed in this order on the substrate 2. The material of the first electrode film 111 is Ti, for example. The thickness of the first electrode film 111 is 5 nm, for example. The material of the second electrode film 112 is Cu or Ni, for example. The thickness of the second electrode film 112 is 100 nm, for example. Alternatively, a single-layer electrode film may be formed in place of the electrode films 111 and 112.

Next, as shown in FIG. 5, the first layer 12 is formed on the electrode film 11 by electroplating using the electrode film 11 as an electrode. The material of the first layer 12 is Cu, for example. The thickness of the first layer 12 is 8 μm, for example. When the first layer 12 is formed by electroplating, it is preferred to adjust the sizes of precipitation grains by controlling the composition of plating bath and the current density.

Next, as shown in FIG. 6, the top surface of the first layer 12 is flattened by polishing. A method of this polishing is CMP, for example. The method of polishing the top surface of the first layer 12 is not limited to CMP but may be any other polishing method such as buffing, lapping and die polishing. The processing of flattening the top surface of the first layer 12 may be performed by a combination of two or more polishing methods. It is not necessary to flatten the top surface of the first layer 12 by polishing in such a case that the surface roughness in maximum height Rz of the top surface of the first layer 12 is made sufficiently small without flattening the top surface of the first layer 12.

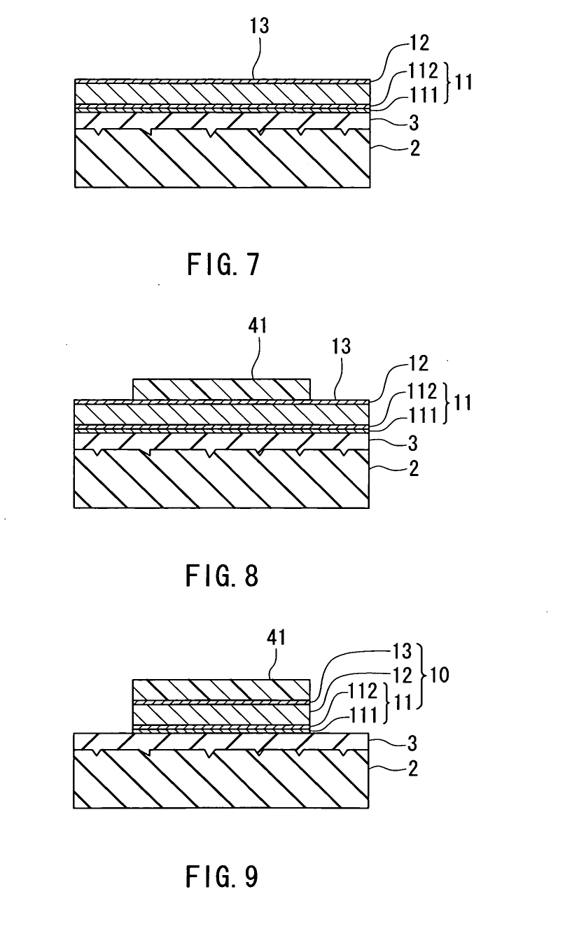

Next, as shown in FIG. 7, the second layer 13 is formed on the first layer 12 by PVD or CVD. Here, by way of example, the material of the second layer 13 is Cr and the second layer 13 is formed by sputtering. The thickness of the second layer 13 is 0.3 μm, for example.

FIG. 8 illustrates the following step. In the step, first, a photoresist layer having a thickness of 8 μm, for example, is formed on the second layer 13. Next, the photoresist layer is patterned by photolithography to form an etching mask 41. The etching mask 41 has a plane geometry corresponding to the plane geometry of the lower conductor layer 10 to be formed.

Next, as shown in FIG. 9, the second layer 13, the first layer 12 and the electrode film 11 are selectively etched by dry etching using the etching mask 41. The lower conductor layer 10 is thereby formed of the remaining electrode film 11, first layer 12 and second layer 13. The etching mask 41 is then removed.

In the steps shown in FIG. 5 to FIG. 9, the lower conductor layer 10 is formed by forming the first layer 12 and the second layer 13 one by one on the electrode film 11 and then patterning the second layer 13, the first layer 12 and the electrode film 11. In place of this method, the lower conductor layer 10 may be formed by, after the first layer 12 is formed on the electrode film 11, patterning the first layer 12 and the electrode film 11 and then forming the second layer 13 on the first layer 12.

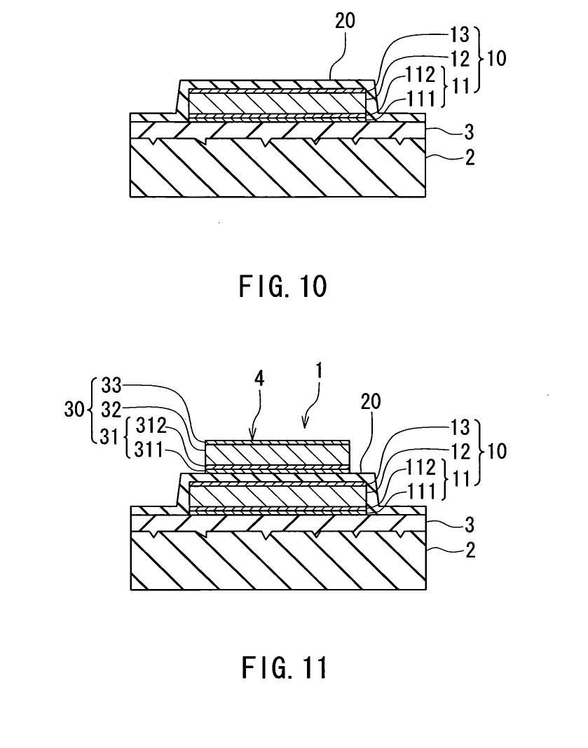

Next, as shown in FIG. 10, the dielectric film 20 is formed by sputtering, for example, to cover the top and side surfaces of the lower conductor layer 10 and the top surface of the flattening film 3. The thickness of the dielectric film 20 is 0.1 μm, for example.

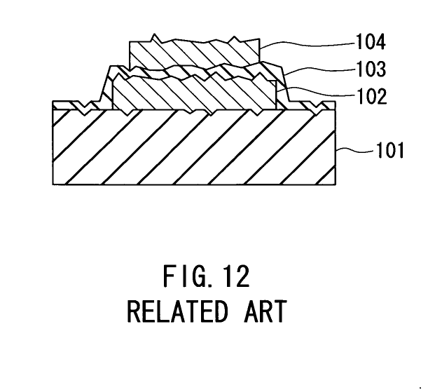

Next, as shown in FIG. 11, the upper conductor layer 30 is formed in a region that is on the dielectric film 20 and that sandwiches the dielectric film 20 with the lower conductor layer 10. A method of forming the upper conductor layer 30 is the same as that of the lower conductor layer 10 except the flattening processing, for example. That is, the electrode film 31 is first formed on the dielectric film 20. Here, by way of example, the electrode film 31 is made up of two layers including a first electrode film 311 and a second electrode film 312. The first electrode film 311 and the second electrode film 312 are formed in this order on the dielectric film 20. The materials and thicknesses of the electrode films 311 and 312 are the same as those of the electrode films 111 and 112 of the lower conductor layer 10. Next, the first layer 32 is formed on the electrode film 31 by electroplating using the electrode film 31 as an electrode. The material and thickness of the first layer 32 are the same as those of the first layer 12 of the lower conductor layer 10. Next, the second layer 33 is formed on the first layer 32 by PVD or CVD. The material and thickness of the second layer 33 are the same as those of the second layer 13 of the lower conductor layer 10. Next, an etching mask is formed on the second layer 33. Next, the second layer 33, the first layer 32 and the electrode film 31 are selectively etched by dry etching using the etching mask. The upper conductor layer 30 is thereby formed of the remaining electrode film 31, first layer 32 and second layer 33. The etching mask is then removed.

According to the embodiment as thus described, the lower conductor layer 10 incorporates: the first layer 12 formed by electroplating; and the second layer 13 formed by PVD or CVD and disposed between the first layer 12 and the dielectric film 20. Each of the first layer 12 and the second layer 13 is made of a metal. The grain diameter of the metallic crystal of the second layer 13 is smaller than that of the first layer 12.

In the first layer 12 as it is formed, there may exist portions that have not reached the equilibrium state wherein the process of metallic crystal growth has not completed. Therefore, if the dielectric film 20 is formed directly on the first layer 12 within a relatively short period of time after the first layer 12 is formed, unreacted residual substances existing in the portions of the first layer 12 that have not reached the equilibrium state may diffuse into the dielectric film 20. As a result, there is a possibility that the characteristics of the dielectric film 20 such as permittivity and dielectric loss tangent may change to become different from those intended. In addition, if the dielectric film 20 is formed directly on the first layer 12 within a relatively short period of time after the first layer 12 is formed, the first layer 12 is heated in the course of forming the dielectric film 20, which may cause a change in the state of the portions of the first layer 12 that have not reached the equilibrium state, and consequently the surface roughness of the top surface of the first layer 12 touching the dielectric film 20 may be increased.

In the embodiment, in contrast, the second layer 13 formed by PVD or CVD is disposed between the first layer 12 and the dielectric film 20. The grain diameter of the metallic crystal of the second layer 13 is smaller than that of the first layer 12. The second layer 13 formed by PVD or CVD is in a nearly equilibrium state as it is formed. According to the embodiment, since the second layer 13 having such characteristics is disposed between the first layer 12 and the dielectric film 20, it is possible to prevent residual substances present in the portions of the first layer 12 that have not reached the equilibrium state from diffusing into the dielectric film 20 and it is also possible to prevent an increase in surface roughness of the top surface of the lower conductor layer 10 touching the dielectric film 20 (that is, the top surface of the second layer 13) in the course of forming the dielectric film 20. As a result, according to the embodiment, it is possible to prevent a change in characteristics of the dielectric film 20 and a reduction in uniformity of the thickness of the dielectric film 20 resulting from the portions of the first layer 12 that have not reached the equilibrium state. It is thereby possible to prevent the characteristics of the capacitor 4 from differing from those intended, and to suppress a reduction in withstand voltage of the capacitor 4 and increases in variations in characteristics and withstand voltage of the capacitor 4 among products.

The top surface of the second layer 13 formed by PVD or CVD is easier to be flattened than the top surface of the first layer 12 formed by electroplating. Therefore, it is easy to make the surface roughness in maximum height Rz of the top surface of the second layer 13 smaller than that of the top surface of the first layer 12. According to the embodiment, it is thereby possible to improve the uniformity of the thickness of the dielectric film 20. This also makes it possible to suppress a reduction in withstand voltage of the capacitor 4 and an increase in variation in withstand voltage of the capacitor 4 among products.

According to the embodiment, since the thickness of the dielectric film 20 is made uniform, it is possible to make the dielectric film 20 thin while maintaining a sufficient withstand voltage of the capacitor 4. As a result, in cases where capacitors having the same capacitances are to be implemented, it is possible to reduce the area of a region in which the lower conductor layer 10 and the upper conductor layer 30 are opposed to each other with the dielectric film 20 disposed in between and to reduce the number of conductor layers and dielectric films to be stacked. It is thereby possible to achieve reductions in dimensions and profile of the thin-film device.

Furthermore, according to the embodiment, since it is possible to make the surface roughness of the top surface of the lower conductor layer 10 small, it is possible to reduce the skin resistance of the lower conductor layer 10. As a result, it is possible to prevent degradation of the signal transmission characteristic of the lower conductor layer 10 when the thin-film device 1 is designed for high frequency applications.

In the embodiment, after the first layer 12 is formed by electroplating, heat treatment may be performed on the first layer 12 in a vacuum environment and inverse sputtering may be further performed on the surface of the first layer 12 before the second layer 13 is formed on the first layer 12 by PVD or CVD. In this case, the heat treatment performed on the first layer 12 forces the first layer 12 into the equilibrium state, and inverse sputtering performed on the surface of the first layer 12 improves the contact of the surface of the first layer 12 with the second layer 13.

In the embodiment, inverse sputtering may be performed before forming the dielectric film 20 to remove unwanted substances such as oxides and organic substances present on the surface of the lower conductor layer 10 and to activate the surface of the lower conductor layer 10 so as to improve the contact of the surface of the lower conductor layer 10 with the dielectric film 20. In this case, in particular, processing of improving the contact of the surface of the lower conductor layer 10 with the dielectric film 20 and processing of forming the dielectric film 20 may be performed consecutively in a single vacuum chamber, so that the contact of the lower conductor layer 10 with the dielectric film 20 is further improved.

It is also possible that, before forming the electrode film 11 or 31, inverse sputtering is performed to remove unwanted substances such as oxides and organic substances present on the surface of the base of the electrode film 11 or 31 and to improve the contact of the surface of the base with the electrode film 11 or 31.

In the case of performing inverse sputtering after the dielectric film 20 is formed and before the electrode film 31 is formed, it is necessary to adjust the conditions for the inverse sputtering such as the output, gas flow rate, and process time so as to prevent a reduction in thickness of the dielectric film 20 and damage to the dielectric film 20.

The present invention is not limited to the foregoing embodiment but may be practiced in still other ways. For example, in the thin-film device of the invention, a protection film may be provided on the upper conductor layer 30, or the upper conductor layer 30 may be exposed. Furthermore, one or more additional layers may be provided above the upper conductor layer 30.

In the invention, another dielectric film and conductor layer may be alternately stacked in a total of two or more layers on the top surface of the upper conductor layer 30. As a result, it is possible to form a capacitor having a configuration in which conductor layers and dielectric films are alternately stacked on a total of five or more layers.

The lower conductor layer, the dielectric film and the upper conductor layer of the invention are not limited to the ones constituting a capacitor. For example, each of the lower conductor layer and the upper conductor layer may make up an individual signal line, and the dielectric film may be used to insulate the lower and upper conductor layers from each other.

The thin-film device of the invention may include elements other than a capacitor. Such elements may be passive elements such as inductors and resistors, or may be active elements such as transistors. Such elements may be lumped-constant elements or distributed-constant elements.

The thin-film device of the invention may comprise terminals disposed on sides, the bottom surface or the top surface. The thin-film device of the invention may comprise through holes for connecting a plurality of conductor layers. The thin-film device of the invention may comprise conductor layers for wiring for connecting the lower conductor layer 10 or the upper conductor layer 30 to terminals or other elements. Alternatively, portions of the lower conductor layer 10 or the upper conductor layer 30 may also serve as the terminals, or the lower conductor layer 10 or the upper conductor layer 30 may be connected to the terminals via through holes.

If the thin-film device of the invention incorporates a capacitor and elements other than the capacitor, the thin-film device may be used as a variety of circuit components including a capacitor, such as LC circuit components, various filters including low-pass filters, high-pass filters and band-pass filters, diplexers, and duplexers.

The thin-film device of the invention is utilized for a mobile communications apparatus such as a cellular phone and a communications apparatus for a wireless LAN.

Obviously many modifications and variations of the present invention are possible in the light of the above teachings. It is therefore to be understood that within the scope of the appended claims the invention may be practiced otherwise than as specifically described.

What is claimed is:

1. A thin-film device comprising:
a lower conductor layer;
a dielectric film disposed on the lower conductor layer; and
an upper conductor layer disposed on the dielectric film, wherein:
the lower conductor layer incorporates: a first layer made of a metal; and a second layer made of a metal and disposed between the first layer and the dielectric film; and
a grain diameter of a metallic crystal of the second layer is smaller than that of the first layer.

2. The thin-film device according to claim 1, wherein a surface roughness in maximum height of a top surface of the second layer is smaller than that of a top surface of the first layer.

3. The thin-film device according to claim 1, wherein the dielectric film has a thickness that falls within a range of 0.02 to 1 μm inclusive.

4. The thin-film device according to claim 1, wherein the metal forming the first layer contains any of Cu, Ag and Al, and the metal forming the second layer contains any of Cu, Ag, Al, Cr, Ti, Ni, Ni—Cr and Au.

5. The thin-film device according to claim 1, wherein the lower conductor layer, the dielectric film and the upper conductor layer constitute a capacitor.

6. A method of manufacturing a thin-film device comprising a lower conductor layer, a dielectric film disposed on the lower conductor layer, and an upper conductor layer disposed on the dielectric film, wherein: the lower conductor layer incorporates a first layer made of a metal and a second layer made of a metal and disposed between the first layer and the dielectric film, the method comprising the steps of
forming the first layer by electroplating;
forming the second layer on the first layer by physical vapor deposition or chemical vapor deposition;
forming the dielectric film on the second layer; and
forming the upper conductor layer on the dielectric film.

7. The method according to claim 6, wherein a grain diameter of a metallic crystal of the second layer is smaller than that of the first layer.

8. The method according to claim 6, wherein a surface roughness in maximum height of a top surface of the second layer is smaller than that of a top surface of the first layer.

9. The method according to claim 6, wherein the dielectric film has a thickness that falls within a range of 0.02 to 1 μm inclusive.

10. The method according to claim 6, wherein the metal forming the first layer contains any of Cu, Ag and Al, and the metal forming the second layer contains any of Cu, Ag, Al, Cr, Ti, Ni, Ni—Cr and Au.

11. The method according to claim 6, wherein the lower conductor layer, the dielectric film and the upper conductor layer constitute a capacitor.
